(19) United States
(12) Patent Application Publication
(10) Pub. No.: US 2004/0154528 A1
(43) Pub. Date: Aug. 12, 2004

(54) Method for making synthetic gems comprising elements recovered from humans or animals and the product thereof

(76) Inventor: Robert E. Page JR., Streamwood, IL (US)

Correspondence Address: LEYDIG VOIT & MAYER, LTD, 6815 WEAVER ROAD, ROCKFORD, IL, 61114-8018, US

(21) Appl. No.: 10/364,286

(22) Filed: Feb. 11, 2003

(51) Int. Cl. C30B 23/00; C30B 25/00; C30B 28/12; C30B 28/14

(52) U.S. Cl. 117/84

(57) ABSTRACT

The invention includes a novel synthetic gem comprising elements recovered from complete or partial human or animal remains. The invention also includes the process of manufacturing synthetic gems comprising carbon from a vertebrate by cremating human or animal remains to produce carbon in a particulate and gaseous form. The carbon is then filtered using a conventional filtering technique. The carbon and other elements are then purified and graphetized. The gems are then created using conventional sublimation techniques. The synthetic gems may be faceted and polished utilizing conventional faceting and polishing techniques. The gems may also utilize a conventional marking system.

### FIELD OF THE INVENTION

This invention relates to a method for making synthetic gems comprising elements recovered from complete or partial human or animal remains and tissue from living humans or animals. This invention also relates to synthetic gems comprising elements recovered from complete or partial human or animal remains and tissue from living humans or animals.

### BACKGROUND OF THE INVENTION

Synthetic gems have been manufactured since the 1960s as an attempt to substitute for naturally occurring gems. Advances in the methods of manufacture have made it possible to produce synthetic gems of equal or better appearance than naturally occurring gems. Examples of these synthetic gems include the synthetic diamonds disclosed in U.S. Pat. No. 4,042,673, and the moissanite gems disclosed in, U.S. Pat. Nos. 5,762,896, 6,025,289, and 6,200,917.

Even though synthetic gems can be indistinguishable from naturally occurring gems to the untrained eye, a trained person in the jewelry field can easily distinguish between naturally occurring and synthetic gems by using the following methods, among others: viewing the refraction lines under a microscope, viewing metallic inclusions through the microscope, subjecting synthetic gems to shortwave ultraviolet light and viewing patterns caused by seed crystals under the microscope. Because of the relative ease with which a trained person can distinguish synthetic gems from naturally occurring gems, the synthetic gem's value is much lower than that of a naturally occurring gem. These factors have severely limited the appeal of the synthetic gems, and the success of the synthetic gem business as a whole. In the case of synthetic diamonds the cost to produce them is equal to, or more expensive than natural gem quality diamonds. Because of these factors, naturally occuring gems remain much more popular and valuable than synthetic gems.

Producers of synthetic gems are currently using graphite that is mined from beneath the earth's surface, or synthetic graphite made from burning wood in the absence of oxygen, as their source of carbon for producing synthetic gems. This carbon source cannot be traced to any specific vertebrate, and therefore a gem produced from this source would have several disadvantages when compared to the present invention: a synthetic gem made from mined graphite would not be used as a memorial gem in a memorial or funeral service for a deceased human or animal; a synthetic gem made from mined graphite would not be used as a keepsake that preserves the remains and memories of the deceased for bereaved family, friends, loved ones, lovers, or acquaintances; a synthetic gem made from mined graphite would not provide a symbol of the bond between two individuals who wish to express their commitment by providing ingredients to a single synthetic gem; and a synthetic gem made from mined graphite would not produce a unique collectable gem celebrating a famous person.

### BRIEF SUMMARY OF THE INVENTION

A broad aspect of the invention comprises a novel synthetic gem comprising elements recovered from complete or partial human or animal remains. The present invention also includes the method for making a synthetic gem comprising elements recovered from complete or partial human or animal remains.

It is, therefore, an aspect of the present invention to provide a novel synthetic gem comprising elements recovered from complete or partial human remains. It is also an aspect of the present invention to provide a method for making a synthetic gem comprising elements recovered from complete or partial human remains. It is yet another aspect of the present invention to provide a novel synthetic gem comprising elements recovered from complete or partial animal remains. It is still another aspect of the present invention to provide a method for making a synthetic gem comprising elements recovered from complete or partial animal remains. It is another aspect of the present invention to provide a synthetic gem to be used in a memorial or funeral service for a deceased human or animal.

It is a further aspect of the present invention to provide a synthetic gem to be used as a permanent keepsake that preserves the remains and memories of the deceased with a diamond-quality gem for bereaved family, friends, loved ones, lovers, or acquaintances. It is still another aspect of the present invention to provide a synthetic gem which is a symbol of the bond between two individuals who wish to express their commitment by providing ingredients to a single synthetic gem. It is yet another aspect of the present invention to provide a synthetic gem which provides a unique authenticated collectable gem celebrating a famous person. Accordingly, the present invention eliminates the disadvantages of natural gems which cannot be traced to any specific vertebrate.

The process of manufacturing synthetic gems comprising carbon from a vertebrate comprises the steps of cremating human or animal remains to produce carbon in a particulate and gaseous form. The carbon is then collected or filtered using a conventional collection or filtering technique. The carbon and other elements are then purified and graphetized, using a High Temperature Vacuum Induction Purification technique. The gems are then created using conventional sublimation techniques. The synthetic gems may be faceted and polished utilizing conventional faceting and polishing techniques. The gems may also utilize a conventional marking system.

In use, the synthetic gem can function as a memorial item to be used in a funeral or memorial ceremony by survivors, family, friends, loved ones, and acquaintances.

In addition, it can be used to remember a deceased loved one by mounting it in a number of different ways including, but not limited to: keepsakes, memorials, mementos, collectors items, loose gems, gems set in rings, watches, bracelets, pendants, earrings, anklets, waist bands, ornaments, crucifixes, rosaries, necklaces, statues, figurines, sculptures, art work, or custom gold, silver, platinum, brass, bronze, stainless steel, or copper settings.

In another aspect of the present invention, the remains of any endeared species (human remains, dog, cat remains) may be chemically mixed, bonded with diamonds, precious gems/stones, semi-precious gems/stones, glasses, glazes and crystals created synthetically by use of diamond making machines, and other known synthetic gem manufacturing apparatus. Some of the known processes/methods for precious and semi-precious gem/stone manufacturing that may be applicable to this additional aspect include but are not limited to the following: the Verneuil method, the Flux Fusion process, the Flux-melt process, the hydrothermal transport and recrystalization process, other hydrothermal processes, the skull melt process, the crystallization from a melt process, the Czochralsky process, and variations on/of the previously mentioned methods/processes. The ashes/remains are to be treated and mixed with known gem making mixtures prior to submitting the mixture to the method/process to manufacture a material or gem. The material may be re-mixed at a later time and subjected to the same or differing processes for one or more trials.

In yet a further embodiment of the present invention, the manufacture of diamonds using human/animal remains is to be completed using any number of known methods. The human/animal remains prior to dessication/heating/cremation may be referred to as the “subject”. These methods include but are not limited to the following: collection of carbon from a gaseous phase during the heating/cremation process, heating the subject at a temperature at or lower than that necessary for cremation in order to facilitate the collection/formation of carbon. In addition, this may be done in a low oxygen environment. In order to collect carbon suitable for diamond creation the subject may be heated in a contained/controlled environment for example a reusable or one time use stainless steel containment vessel that may have filtered collection vents or vents which draw the carbon/volatile material/gas through a filter or collection chamber prior to final dispersion. The diamond mixtures or diamond making formulas and synthetically creating the diamonds with known diamond making devices. The diamonds generated from the human/animal carbon may be re-mixed with other diamonds or mixtures and re-subjected to the diamond making devices or other processes for one or more trials in order to increase the size of the final product or enhance the final product. The carbon may also be purified and/or converted into graphite.

The synthetic diamonds, gems, semi-precious gems, glasses, crystals or other synthetic materials produced may be faceted or cut into any number of previously known or as yet to be known designs in various embodiments. The cut/faceted synthetic diamonds, gems, semi-precious gems, glasses, crystals or other synthetic materials produced may be mounted or included in rings, necklaces, bracelets or other fixtures or mountings.

Some of the final products of the previously mentioned methods/processes shall include but not be limited to the following synthetic materials: Diamond, Corundum, Ruby, Sapphire, Star Sapphire, Sapphire variations, Spinel and Spinel variations, Garnets and Garnet variations, Beryl/Emerald and variations, Olivene/Peridote/Diopside and variations, Zircons and variations, Rutile and variations, Strontium titanate and variations, quartz and variations, glass and variations, crystals of the previously mentioned materials and variations thereof, and lead crystal and variations.

There has thus been outlined, rather broadly, the more important features of the invention in order that the detailed description thereof that follows may be better understood, and in order that the present contribution to the art may be better appreciated. There are, of course, additional features of the invention that will be described hereinafter and that will form the subject matter of the invention. Those skilled in the art will appreciate that the conception, upon which this disclosure is based, may readily be utilized as a basis for the designing of other devices or methods for carrying out the several purposes of the present invention. It is important, therefore, that the invention be regarded as including such equivalent constructions and methods insofar as they do not depart from the spirit and scope of the present disclosure.

### BRIEF DESCRIPTION OF THE DRAWINGS

There are no drawings.

### DETAILED DESCRIPTION OF THE INVENTION

While the invention will be described in connection with certain preferred embodiments, there is no intent to limit it to those embodiments. On the contrary, the intent is to cover all alternatives, modifications and equivalents as included within the spirit and scope of the invention as defined by the appended claims.

The present invention is a novel synthetic gem comprising elements recovered from complete or partial human or animal remains. The present invention also includes the method for making a synthetic gem comprising elements recovered from complete or partial human or animal remains.

The process of manufacturing synthetic gems comprising carbon from a vertebrate begins with one of several conventional cremation processes well-known in the art. Cremation as defined by World Book Encyclopedia “is burning a dead body to ashes.” The cremation is performed in a building called a crematory or crematorium. The body is put in a coffin or other container, which is burned in a special oven for several hours. The body is generally burned at a temperature that can range from approximately 1000 degrees Fahrenheit up to approximately 1800 degrees Fahrenheit. In order to facilitate higher airborne particulate carbon levels, a higher gas to air ratio is used so that the gas burners cremate the body at the low end of the temperature range. This cremation process produces sufficient carbon in particulate and gaseous form, and is collected using filtering or collection techniques. The cremation processes that could be used include, but are not limited to those described in the following patents: U.S. Pat. Nos. 5,957,065 and 4,603,644 and the U.S. Patents cited therein.

Carbon elements produced during the cremation process are collected using one of several conventional collection or filtering techniques before these gases escape into the air from the smokestack of the cremation oven. The filtering or other techniques that could be used for this process include, but are not limited to: electrostatic filtering, dry scrubbing, cartridge filtering, and wet scrubbing, as described in but not limited to the following patents: U.S. Pat. Nos. 5,406,582, 5,198,001, 6,241,809, 6,231,648, 6,231,643, 6,110,256, 6,113,795, 6,106,592, 6,096,118, 6,203,600 and 6,193,782. The preferred process for carbon collection is to retrieve the carbon from the cremation oven after the body has been cremated. The preferred process for collection begins with the oven operator positioning the body in the oven so that the head and chest area are not positioned directly underneath the main burner. This can be accomplished by positioning the body to the left or right side of the main burner, or positioning the body so that the legs and feet are underneath the main burner rather than the head and torso. Positioning the body in this manner assures that carbon will remain in the body's head area. The carbon can then be gathered by hand, or by using a metal shovel or scoop, or the like. Alternatively, one or more body parts may be cremated.

An alternative process for carbon collection is using a filter system. The filtering is accomplished by use of a horizontal cartridge dust collector with special high temperature fiberglass filter cartridges with 2” pleats, ceramic potting, and temperature resistant silicone gasketing. The filters are capable of handling temperatures of 500 degrees Fahrenheit, and 2400 cfm of air flow. The total filter area is 996 square feet and provides an air to cloth ratio of 4: 1. This ratio is needed in order to bleed in approximately 65% of ambient air to cool the air below 500 degrees Fahrenheit. A 7.5 horsepower motor/blower is included in the filter housing to provide up to 4000 cfm air flow to maintain proper flow through the filter media. The carbon particles will be removed from the filter with reverse pulses of air, and deposited in a metal drawer below the filter cartridges.

Another alternative embodiment for carbon collection involves collecting carbon from pulverized cremated remains. These remains consist mostly of ash, but depending on how the cremation was performed, there may be traces of carbon particles mixed in with the ashes. The remains can be placed in a vacuum induction furnace. The furnace is heated to 2000 degrees centigrade in a vacuum ranging from 30 toir to 500 torr. Chlorine gas is injected into the furnace, and reacts with the impurities to form chlorides. The impurities leave the carbon in the form of chloride gases, and are filtered as they exit the furnace. The ash is removed leaving carbon. Once these particles of carbon have been collected, they are purified, and graphetized.

The carbon and other elements are purified, and graphetized using conventional carbon purification techniques. The preferred purification technique is Halogen Purification. This is done with the use of a High Temperature Vacuum Induction Furnace. The High Temperature Vacuum Induction Furnace utilizes vacuum pressure in the range of 30 torr to 500 torr and a temperature up to 3000 degrees Centigrade. Chlorine gas is injected into the furnace, and reacts with the impurities to form chlorides. The impurities leave the carbon in the form of chloride gases, and are filtered as they exit the furnace. After the impurities have been removed, the carbon that remains is pure within 10 ppm. In addition to being pure withnin 10 ppm, the carbon also becomes graphetized by the high temperatures. It is necessary to provide graphite for the crystal growth process.

Using the process of crystal growth from sublimation according to techniques of the type described but not limited to the process described in U.S. Pat. Nos. 34,061, 6,200,917, 6,025,289, 6,045,613, 4,042.673 and 5,762,896, the purified/graphetized carbon from vertebrates is used to replace or supplement purified/graphetized carbon of non-vertebrates, and processed into synthetic gems comprising carbon from vertebrates.

The synthetic gems may be faceted and polished utilizing conventional faceting and polishing techniques, which are well-known in the art.

The gems, as a client selected option, may utilize a laser marking system such as that disclosed in U.S. Pat. No. 6,211,484 in order to mark each gem with it's own individual identification corresponding to the vertebrate which supplied at least a portion of the carbon for the gem.

In use, the synthetic gem can function as a memorial item to be used in a funeral or memorial ceremony by survivors, family, friends, loved ones, and acquaintances.

In addition, it can be used to remember a deceased loved one by mounting it in a number of different ways including, but not limited to: keepsakes, memorials, mementos, collectors items, loose gems, gems set in rings, watches, bracelets, pendants, earrings, anklets, waist bands, ornaments, crucifixes, rosaries, necklaces, statues, figurines, sculptures, art work, or custom gold, silver, platinum, brass, bronze, stainless steel, or copper settings.

The resulting synthetic gem quality crystal comprising carbon from a vertebrate has a unique character to it, because it specifically relates to the vertebrate which supplied at least a portion of the carbon for the gem. This personal touch makes it much more valuable and meaningful to the owner of such a gem. The gem could also be marked with its own individual identification corresponding to the vertebrate that the gem originated from so that it could not be confused with a synthetic gem not comprising carbon from a vertebrate.

Hence, while the invention has been described in connection with a preferred embodiment and method, it will be understood that it is not intended that the invention be limited to that embodiment and method. On the contrary, it is intended to cover all alternatives, modifications and equivalents as may be included within the spirit and scope of the invention as disclosed.

As to the manner of usage and operation of the instant invention, same should be apparent from the above disclosure, and accordingly no further discussion relevant to the manner of usage and operation of the instant invention shall be provided.

With respect to the above description then, it is to be realized that the optimum proportions for the elements of the invention, and variations in size, materials, shape, form, function and manner of operation, assembly and use, are deemed readily apparent and obvious to one skilled in the art, and all equivalent relationships described in the specification are intended to be encompassed by the present invention.

Therefore, the foregoing is considered illustrative of only the principles of the invention. Further, since numerous modifications and changes will readily occur to those skilled in the art, it is not desired to limit the invention to the exact method, construction and operation shown and described, and accordingly, all suitable modifications and equivalents may be resorted to, falling within the scope of the invention.

In a further embodiment of the present invention, a method of memorializing the remains of a living thing or a former living thing (subject) that produces a gem, or object of beauty is presented. The subject is to be defined as a human or any endeared species (dog, cat, etc.) The method comprises the collection of chemicals and ask during and/or after the cremation (remains) of the subject, or a portion of the subject which may be diseased or still living (hair, fingernails etc.), which shall then be used to produce a gem, semi-precious gem or gem-like synthetic or stimulant or mineral memorial. Various amount of the remains ranging from 100 percent to trace percentages are to be utilized and potentially mixed with other chemicals to produce a man-made gem, gem-like material, other crystalline forms, glass or glass-like material, ceramic, or other material. The material would be preferably transparent or translucent. The material could then be faceted into a gemstone or molded, carved, sculpted or otherwise fashioned into a lasting aesthetic memorial. The memorial object could then be inscribed, etched or otherwise tagged with descriptive identification indicative of the living being from which the remains have been obtained. Various methods of recovery of elements or chemicals from the remains are to include but not be limited to leaching, absorption, reduction, and other refining and capture procedures. Carbon could be captured at various stages of the cremation process, and/or by heating within a controlled atmosphere environment, capture from a vapor or particulate phase or other known methods.

The Chemicals known to be present in the bodies of humans and many other animals include: Carbon (C), Hydrogen (H), Oxygen (O), Phosphorus (P), Potassium (K), Iodine (I), Nitrogen (N), Sulphur (S), Calcium (Ca), Iron (Fe), Sodium (Na), Chlorine (Cl), Magnesium (Mg), Manganese (Mn), Zinc (Zn), and trace amounts of Selenium (Se), Cobalt (Co), Chromium (Cr), Copper (Cu) and others. The approximate composition of human ash is as follows and is similar to that of many other typically endeared animals:

CaO 39.0%

P205 50.2%

K20 4.8%

Na203 3.8%

MgO 0.9%

SiO2 1.1%

Fe203 0.2%

ZnO 0.1%

There are many known procedures used to create man-made gems and gem-like materials and there are many naturally occurring gems that have not been synthesized commercially or otherwise. In this embodiment of the gem making procedure of the present invention the chemicals within the subject will be collected from the subject during and/or after the cremation procedure, or from materials collected from a living subject (hair, fingernails, etc.). The chemicals will be processed in such a fashion as to isolate and purify the chemicals or elements needed for the particular gem or gem-like material that they will be used to create. Trace elements can be added to the gem during the gem making procedure to produce the desired color (red, blue, green, etc.).

To make a diamond the carbon will be collected, purified, and converted into graphite prior to being converted into a diamond. To produce some types of garnets, calcium, magnesium, or iron would be isolated and mixed with other necessary chemicals to produce a garnet-like gem. To produce a synthetic spinel variety, the magnesium would be collected purified and mixed with other chemicals to produce a synthetic spinel gem. To produce a Moissanite gem (silicon carbide) the carbon would be collected, purified and mixed with silicon and possibly other materials to produce a moissanite gem. To produce a quartz gem material the SiO2 would be collected and purified and mixed with trace elements to yield a desired color. A quartz gem or other silicate material may be produced by adding various amounts of the remains to a mixture that will provide a gem-like or aesthetic memorial.

The materials within the remains may also be processed in a manner to render them additives that may be used to “dope” other gems such as corundum (ruby, sapphire).

There are many synthetic gems that could be doped with trace amounts of chemicals isolated from the remains to yield gem quality memorial. Glass, although not a true gem, has gem-like qualities and can contain sodium and calcium among other chemicals. By isolating certain chemicals present in the remains and adding other chemicals, gems and clear gem like materials can be created and faceted, formed, sculpted or otherwise shaped into an aesthetic lasting memorial.

There are many different processes that can be used to isolate various elements or chemicals from a complex mixture containing those elements or chemicals. Some of those methods include but shall not be limited to leaching, absorption, reduction, controlled atmosphere, particulate collection, and others. There are many different processes used in the gem making industry. Some of them include: Verneuil method, the Flux Fusion process, the Flux-melt process, the hydrothermal transport and recrystalization process, other hydrothermal processes, the skull melt process, the crystallization from a melt process, the Czochralsky process, and variations on/of the previously mentioned methods/processes.

The manufacture of diamonds using human remains is to be completed using any number of known methods. The human/animal remains prior to desiccation/heating/cremation shall be referred to as the “remains”. These methods include but are not limited to the following: collection of carbon from a gaseous phase during the heating/cremation process, or heating the subject at a temperature at or lower than that necessary for cremation in order to facilitate the collection/formation of carbon. The carbon may be collected at a later stage of cremation or after cremation. In addition, this may be done in a low oxygen or controlled oxygen environment. In order to collect carbon suitable for diamond creation the remains may be heated in a contained/controlled environment—for example a reusable or one time use stainless steel containment vessel or other vessel or crematorium that may have filtered collection vents or events which draw the carbon/volatile material/gas through a filter or collection chamber prior to final dispersion. The carbon may also be purified and/or converted into graphite. During the diamond making process a “seed” diamond may be used as a seed for the end diamond product. The diamonds generated from the human carbon may be re-mixed with other diamonds or mixtures and re-subjected to the diamond making devices or other processes for one or more trials in order to increase the size of the final product or enhance the final product.

Carbon suitable for the diamond making process may also be obtained from a currently living thing. Hair, fingernails, fat from liposuction, excised tissue, organs, cancer, limbs, digits, etc. contain carbon and could be reduced to carbon and graphite suitable for the diamond making process. The diamond making process may include but not be limited to mixing the human carbon remains with other carbon mixtures or diamond making formulas and synthetically creating the diamonds with known diamond making devices. Composition of various such gems are listed below:

Diamond: Carbon

Moissanite: (Silicon carbide)

Garnets:

Pyrope: (Fe, Mg)₃ A12Si3O12

Spessarite: Mn3Al2Si3O12

Andradite: Ca3Fe2+³ (Sio4)3

Grossular: Ca3A12 (SiO4)3

Synthetic Garnets

Neodymium gallium garnet

Samarium gallium garnet

Yttrium Aluminum garnet Y3A12(AlO4)3

Garnet can have star effect

Spinel: MgAl204 or MgAl2 or MgO.Al2O3

Spinel can have a star effect

Olivine: (Peridot)(Mg,Fe)2 Sio4

Diopside: (Calcium magnesium silicate) CaMgSi2O6

Epidote: Ca2 (Al,Fe)3 Si3O12 (OH)

Akermanite: Ca2MgSi2O7-Ca2Al2SiO7

Apatite Group: A5(XO4)3(F,Cl,OH)

A=Ca, Sr, Pb, Na, K

X═P, As, V, Si

Scheelite: (Calcium Tungstate)(CaWO4)

Sphalerite: (Zn,Fe)S

Plagioclase: NaAlSi3O8-CaAl2Si2O8

Orthoclase: KalSi3O8

Labradorite: (Na,Ca) AlSi3O8

Microcline: KalSi3)O8

Perovskite: (Calcium Titanate)

Calcium Molybdate Lead Molybdate

Cordierite: (Mg, Fe)2 Al4Si5O18

Tourmaline: (Na, Ca)(Li, Al, Mg, Fe, Mn)3 (Al, Fe)6 B3Si6)27( ), OH, F)4

Ziosite: Ca2Al3Si3)12 OH

Nephrite: (Jade) Ca2(Mg, Fe)5Si8, O22(OH)2

Jadite, a sodium aluminum silicate, can be made by combining sodium carbonate, alumina, and silica. Chromium is added for a green color.

Staurolite: (Fe, Mg, Zn)2 Al9Si4O23(OH)

Pearl: CaCO3

Ivory: Ca8 (F, OH, Cl)(PO4)3

Fluorite: (CaF2)

Lapis Lazuli: (Na,Ca)8 (Al, Si)12O24 (SO41, Sn) A common imitation is a variety of synthetic spinel. Small pieces of gold may be added.

Opal: processed remains could be opalized

Glasses: Window glass usually contains sodium and calcium. Coloring agents can cause blue (cobalt oxide), red (Selenium) yellow-green (uranium compounds), apple green (nickel), and iron yields a variety of colors. Glass can be produced to have a “cats eye” effect. Silver nitrate or silver chloride could also be added to the glass to give an additional aesthetic (rainbow effect)

Quartz: SiO2

There are many varieties of quartz: Rose, Amethyst, Agate, Jasper, Bloodstone, and Carnelian Hydrothermal replacement and other procedures could cause agate varieties and others.

There are many synthetica that could contain trace amount of ashes that could form a gem or a material with gem-like qualities: Corundum: Al2O3

Trace amounts of remains could be incorporated into the corundum making procedure. In corundum, Chromium is used to make ruby, Iron and Titanium are used for the blue color, Iron is used for green, Manganese is used for pink, Vanadium is used for a color that changes depending on the type of light hitting it, and Star Rubies/Sapphires contain titanium. Azurite or Malachite: (Cu2Co3 (OH)2

There are many other mixtures that could be used to create a gem or gem-like material when mixed with trace amounts of remains. These include but are not limited to: Yttrium Aluminum Silicate, Gadolinium Gallium garnet (Gd3, Ga5, o12), Zincite (ZNO), Zircon (Zirconium Silicate), Lanthanum Niobate, Neodymium Niobate, Potassium Niobate, Lithium Niobate, Barium Titanate, Greenockite (Cadmium Sulphide), Germanates (Erbium Germanate and Yttrium Vanadate).

The synthetic diamonds, gems, semi precious gems, glasses, crystals or other synthetic materials produced may be faceted or cut into any number of previously known or as yet to be known designs. The cut/faceted or shaped synthetic materials produced by may be mounted or included in rings, necklaces, bracelets or other fixtures or mountings.

Some of the final products of the previously mentioned methods/processes shall include but not be limited to the following synthetic materials: Diamond, Corundum, Ruby, Sapphire, Star Sapphire, Sapphire variations, Spinel and Spinel variations, Garnets, star Garnets, and Garnet variations, Beryl/Emerald and variations, Olivene/Peridote/Diopside and variations, Zircons and variations, Rutile and variations, Strontium titanate and variations, quartz and variations, glass and variations, crystals of the previously mentioned materials and variations thereof, and lead crystal and variations.

All of the references cited herein, including patents, patent applications, and publications, are hereby incorporated in their entireties by reference.

The foregoing description of various embodiments of the invention has been presented for purposes of illustration and description. It is not intended to be exhaustive or to limit the invention to the precise embodiments disclosed. Numerous modifications or variations are possible in light of the above teachings. The embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A synthetic gem comprising elements recovered from human remains.

2. The gem of claim 1, wherein the elements comprise carbon.

3. A synthetic gem comprising elements recovered from animal remains.

4. The gem of claim 3, wherein the elements comprise carbon.

5. A method of making a synthetic gem comprising elements recovered from human remains comprising the steps of: a) cremating human remains to produce carbon; b) filtering the carbon; c) purifying the carbon; d) graphetizing the carbon; and e) creating gems using crystal growth sublimation.

6. The method of claim 5, further comprising the steps of faceting and polishing the gems.

7. The method of claim 5, further comprising the steps of marking the gems with various indicia.

8. The method of making a synthetic gem comprising elements recovered from animal remains comprising the steps of: a. cremating animal remains to produce carbon; b. filtering the carbon; c. purifying the carbon; d. graphetizing the carbon; and e. creating gems using crystal growth sublimation.

9. The method of claim 8, further comprising the steps of faceting and polishing the gems.

10. The method of claim 8, further comprising the steps of marking the gems with various indicia.
